(19) United States
(12) Patent Application Publication
(10) Pub. No.: US 2007/0065958 A1
(43) Pub. Date: Mar. 22, 2007

(54) Method for attaching an optical filter to an encapsulated package

(76) Inventors: Kean Loo Keh, Penang (MY); Chin Hin Oon, Penang (MY); Chai Liang Loke, Penang (MY); Yong Keong Chin, Bukit Mertajam (MY)

Correspondence Address: AVAGO TECHNOLOGIES, LTD., P.O. BOX 1920, DENVER, CO, 80201-1920, US

(21) Appl. No.: 11/232,308

(22) Filed: Sep. 20, 2005

(51) Int. Cl. H01L 21/00

(52) U.S. Cl. 438/26

(57) ABSTRACT

A method for attaching an optical device to an encapsulated electronic package. The method may include aligning and attaching an optical device to a non-singulated encapsulated electronic package using an adhesive, and curing the entire package. The method may further include singulating the non-singulated encapsulated electronic package with the optical device attached after curing.

### BACKGROUND OF THE INVENTION

In general, photonics, also referred to as optoelectronics, deals with technologies that generate, modulate, guide, amplify, or detect light. The worldwide utilization of photonics devices is growing and adapting at a rapid pace as more and more applications use optoelectronic devices to enhance performance, reduce size, or reduce cost. For example, fiber-optic cables provide much higher bandwidth than conventional copper wires and thus support a broader range of commercial applications, including real-time multimedia applications.

In the area of microelectronics, “packaging” refers to the encapsulation of microelectronic components into a form that can easily be connected into a circuit, i.e., attaching an electronic circuit, e.g., an integrated circuit (“IC”), onto a printed-circuit board (“PCB”), substrate, carrier, or lead-frame resulting in an encapsulated package. In the area of photonics, packaging may also include providing an optical connection, e.g., using an optical filter that is highly directional in nature and requires extremely precise control of positional tolerances between the electronic and the photonics components.

Manufacturing costs of photonics devices have been a drawback to the more widespread use of these devices. Therefore, there is a need to reduce the costs to fabricate photonics components so as make them more viable in commercial applications. A portion of the market for photonics devices deals with high-performance components manufactured in low volume, primarily for military applications, where costs are relatively unimportant. However, there is also a need to develop efficient, high-volume manufacturing processes for commercial applications, such as devices connecting a consumer's electronic equipment to an optical network. It has been estimated that packaging, which includes methods for aligning optical elements and integrating photonics and electronics components, currently accounts for 60 to 80 percent of the manufacturing cost of photonics components.

As an example, FIG. 1 shows an example process of manufacturing a photonics package. In general, this process entails attaching an optical device, which may be an active device such as a transmitter or a receiver, or a passive device, such as an optical filter or an isolator, to an encapsulated package, which typically may include some sort of lens and fibers. The manufacturing process starts in step 102, which is die attachment, i.e., mechanically affixing a silicon wafer containing a single die or multiple dies onto a circuit board, substrate, carrier, or lead-frame. The process then continues to step 104, a wire bonding process, which is the process of providing the electrical connection between the electronic component and the circuit board, substrate, carrier, or lead-frame using bonding wires. In step 106, the process continues to epoxy encapsulation, where the package of the circuit is encapsulated or packaged in a plastic material, which may be silicone or epoxy based.

In the next step 108, singulation, the many individual devices of the encapsulated package produced in step 105 are physically separated into individual encapsulated packages 110 for subsequent packaging with a photonics component. This may be accomplished by sawing, stamping, or laser singulation. It is appreciated by those skilled in the art that these first four steps may be conventional processes originally developed in the semiconductor industry.

The encapsulation process with an optical device starts in step 110, with the application of an adhesive to a single encapsulated package. The adhesive may be a glue, an epoxy resin, a light-curable adhesive, which may include an ultraviolet (“UV”) curable composition, and other attachment means. In step 114, an optical device may be aligned and attached to the encapsulated package utilizing the adhesive applied in step 110. The optical device may be an optical filter that may be fabricated on a large glass substrate. One type of optical filter is an interference filter, where the finished filter may include multiple substrates laminated together to produce a specifically-desired resolution patterning. These filters may be fabricated in the form of a large glass wafer of varying dimensions that may be diced into smaller components in either a circular, square, or rectangular configuration. Once the optical device is attached, the entire package is then cured in step 116, resulting in a completed encapsulated package in step 118.

In FIG. 2, a cross-sectional side view of an example embodiment of a single photonics component 200 produced by the process described in FIG. 1 is shown. The photonics component 200 may include a substrate 202, which may be a plastic or ceramic material, or a metal lead-frame, PCB-based, an electronics component 204, e.g., an Integrated Circuit (“IC”), and an encapsulant 206 that is used to protect the electronic device mechanically and environmentally. Together, these three elements form an encapsulated electronic package. To create a photonics package, a photonics component 210, e.g., an optical filter, is attached to the encapsulated electronic package using an adhesive 208.

Additional steps, e.g., curing, baking, sealing, testing, marking, etc., are utilized to produce the finished product. However, it is appreciated that the main steps of the assembly process are shown in FIG. 1. Additionally, it is appreciated that in the assembly process, creating an optical connection between the photonics component and the electronic component is a difficult aspect of the process because the process needs precise alignment and is highly sensitive to relative movement between the two components.

Therefore, there is a need for an improved method of manufacturing photonics devices that is more efficient and reduces the costs of fabrication associated with the previous methods of manufacture.

### SUMMARY

In general, this invention is a method for attaching an optical device to an encapsulated electronic package prior to singulation in order to reduce misalignment problems, thereby increasing the efficiency of the manufacturing process and reducing the costs of manufacturing. As an example, the method may include applying an adhesive to the encapsulated electronic package in the form of a single component having multiple dies, aligning the optical device relative to the single component, and then attaching the optical device to the single component using the adhesive. The method may also include curing the single component with the attached optical device and then singulating the single component into a plurality of separate encapsulated packages, each with a portion of the optical device attached. By singulating the single component together with the optical device attached, the process cycle time is reduced significantly, and at the same time, problems related to misalignment of the optical filters with a singulated electronic package are also reduced.

As another example of a method for attaching an optical device to an encapsulated electronic package prior to singulation, the method may include dicing an unsingulated optical device having multiple optical devices into a plurality of separated optical devices, applying an adhesive to the single component, aligning each of the separated optical devices relative to the single component, and attaching each of the separated optical devices to the single component using the adhesive. The method may also include curing the single component with the attached plurality of separated optical devices and then singulating the single component with the attached plurality of separated optical devices into a plurality of separate encapsulated packages, each separate encapsulated package with a separated optical device attached to a single die of the encapsulated electronic package. This method also reduces the process cycle time significantly, as well as misalignment and handling-damage problems.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 is a flow chart of an example conventional process for the assembly of photonics components.

FIG. 2 is a cross-sectional side view of an example embodiment of a photonics component produced by the process shown in FIG. 1.

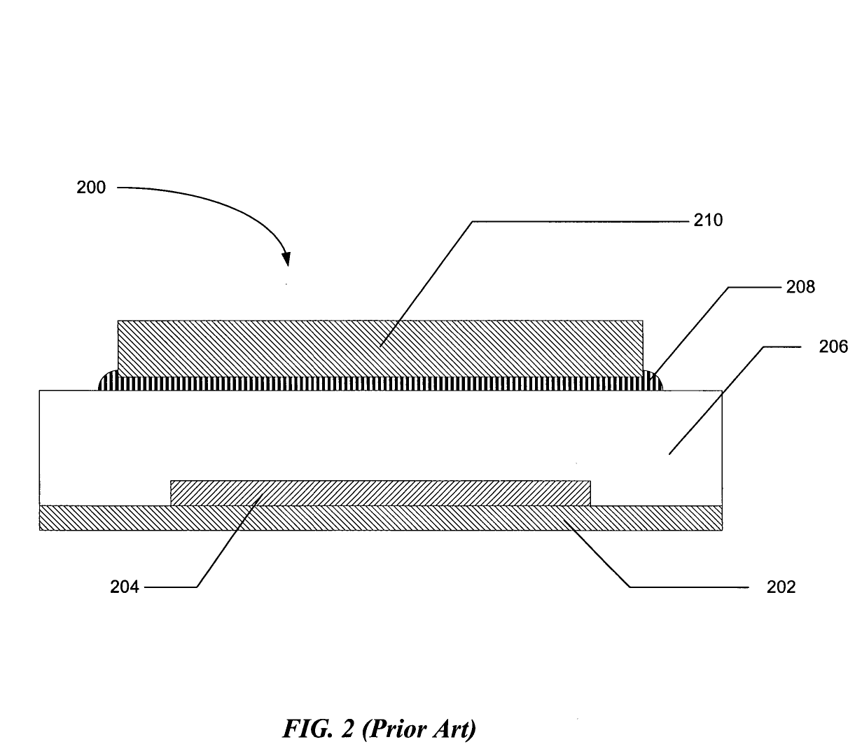

FIG. 3 is a flow chart of an example of an implementation of a process for the assembly of photonics components in accordance with the present invention.

FIG. 4 is a cross-sectional view of an example embodiment of a plurality of photonics components in a single package produced by the process shown in FIG. 3 immediately prior to separation by singulation.

FIG. 5 is a flow chart of another example of an implementation of a process for the assembly of photonics components in accordance with the present invention.

FIG. 6 is a cross-sectional view of an example embodiment of a plurality of photonics components in a single package produced by the process shown in FIG. 5 immediately prior to separation by singulation.

### DETAILED DESCRIPTION

In the following descriptions of example embodiments, reference is made to the accompanying drawings that form a part hereof, and which show, by way of illustration, a specific embodiment in which the invention may be practiced. Other embodiments may be utilized and structural changes may be made without departing from the scope of the present invention.

In general, the invention is a method of attaching an optical device to an encapsulated electronic package prior to singulation in order to reduce misalignment problems, thereby increasing the efficiency of the manufacturing process and reducing the costs of manufacturing.

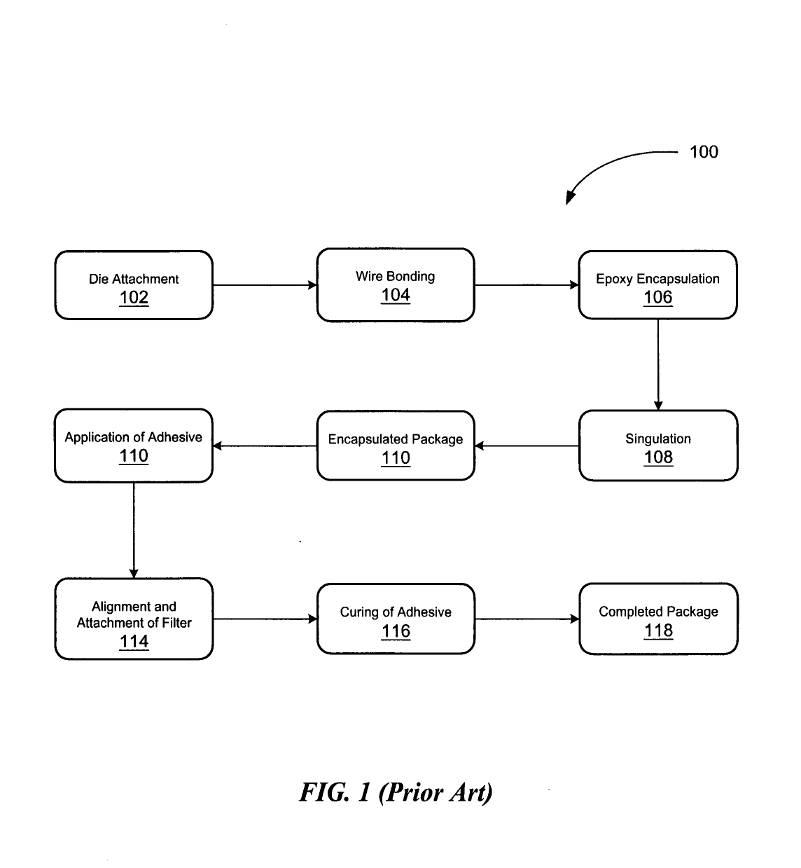

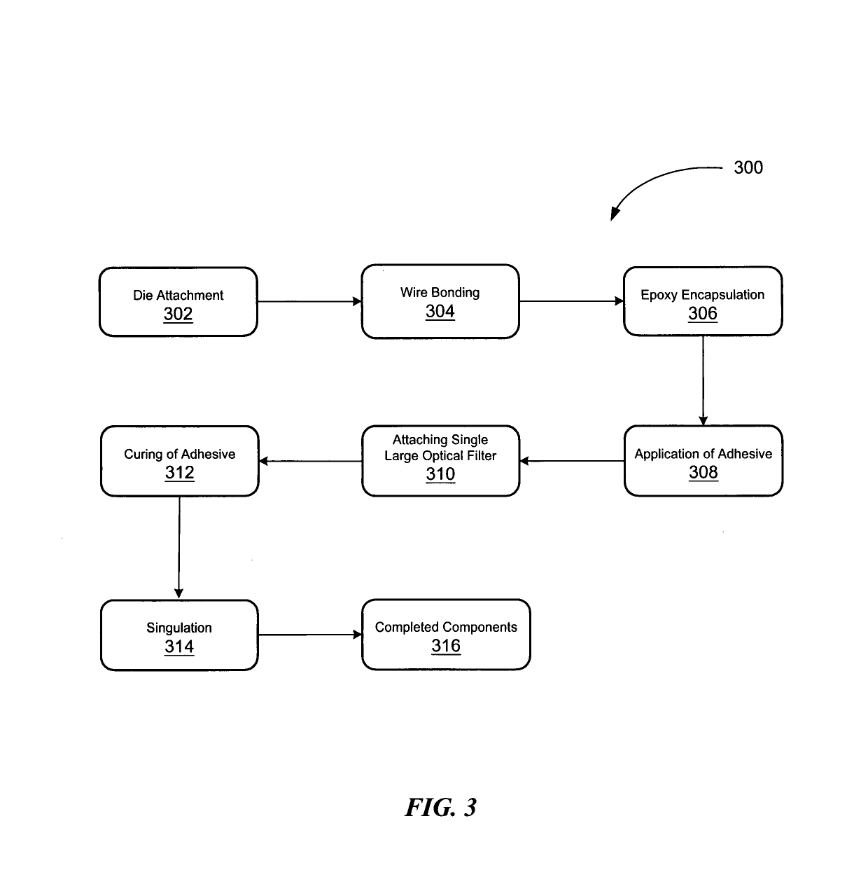

In FIG. 3, a flow chart of an example of an implementation of a process for the assembly of photonics components is shown. Steps 302, 304, and 306 are similar to steps 102, 104, and 106, respectively, of FIG. 1. The process starts in step 302, where an electronic component, e.g., a silicon wafer, containing multiple dies is attached to a circuit board, substrate, carrier, or lead-frame. The process then continues to the wire bonding process of step 304, which is the process of providing the electrical connection between the electronic component and the circuit board, substrate, carrier, or lead-frame using bonding wires. In step 306, the process continues to epoxy encapsulation, where the package of the circuit is encapsulated or packaged in a plastic material, which may be silicone or epoxy based. In step 308, an adhesive is applied to the encapsulated package produced in step 306. Again, the adhesive may be a glue, an epoxy resin, a light-curable adhesive, which may include an ultraviolet (“UV”) curable composition, and other attachment means.

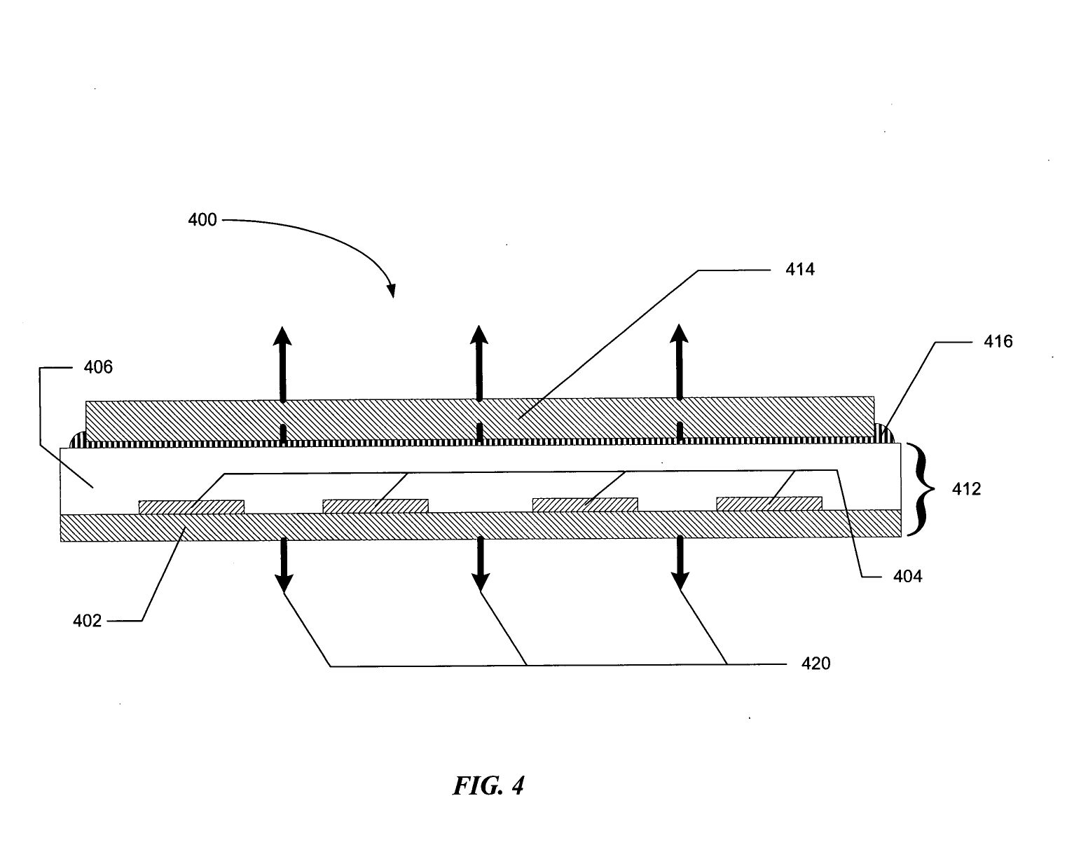

In step 310, a single large optical device is aligned and attached to the encapsulated package. As an example, the optical device may be an optical filter fabricated on a large glass substrate and may include multiple substrates laminated together. Optical filters may also include interference filters, which are filters having multiple layers (thin coatings) of dielectric materials on a substrate where the selection of the materials and the thickness of the layers are chosen to provide specifically-customized resolution patterning, i.e., reflection or transmission of light at a desired wavelength. This large glass wafer may be fabricated to the desired specification and then diced into smaller components of varying configurations. In this example, the glass wafer may be designed to completely cover the encapsulated package, as shown in FIG. 4 (described below).

In step 312, the encapsulated package with the attached optical device is cured. Curing may involve the application of heat or illumination by short-wavelength light depending on the type of adhesive used.

After curing, the encapsulated package is singulated in step 314. It is appreciated by those skilled in the art that there are various methods of singulation, e.g., laser scribing and diamond wheel sawing. As an example, sawing may be utilized to either partially cut or scribe the surface of the encapsulated package, with the encapsulated package then broken along the saw lines, or to completely cut through the encapsulated package. Another example is dry process dicing, where a diamond scribe tool creates a stress line on the encapsulated package and a breaking mechanism fractures the encapsulated package along the stress line. The advantages of this process are narrower dicing cuts and less residual stress in the sides of the encapsulated package.

The process ends in step 316 with multiple photonics components obtained from the singulation of the encapsulated package. Each of these photonics components may require additional processing to obtain the final product, e.g., testing, marking, etc. Marking may include placing corporate and product identification on a photonics component using ink or laser marking.

In FIG. 4, a cross-sectional view of an example embodiment of a single non-singulated package 400 having a plurality of photonics components produced by the process shown in FIG. 3 is shown before it is singulated in step 314 of FIG. 3. In FIG. 4, electronic components 404 are attached to substrate 402 utilizing encapsulant 406. The electronic component 404 and substrate 402 together form an encapsulated package 412. An optical device 414, which in this example may be an optical filter, may be attached to encapsulated package 412 by an adhesive 416 or other attachment means.

In FIG. 4, the single non-singulated package 400 is shown immediately prior to its entry into step 314 as shown in FIG. 3. Sawing lines 420 indicate where the single non-singulated package 400 will be cut. As noted above, singulation may be performed utilizing numerous methods, including, for example, by completely cutting through single non-singulated package 400 using a diamond saw, or by partially sawing and then breaking single non-singulated package 400. In FIG. 4, the sawing along sawing lines 420 creates cuts along the X axis of single non-singulated package 400. It is appreciated that additional cuts along the Y axis may be made to complete the singulation process. In one example method, this may be accomplished by a 90° rotation of the single non-singulated package 400 and repetition of the sawing along the Y axis of single non-singulated package 400.

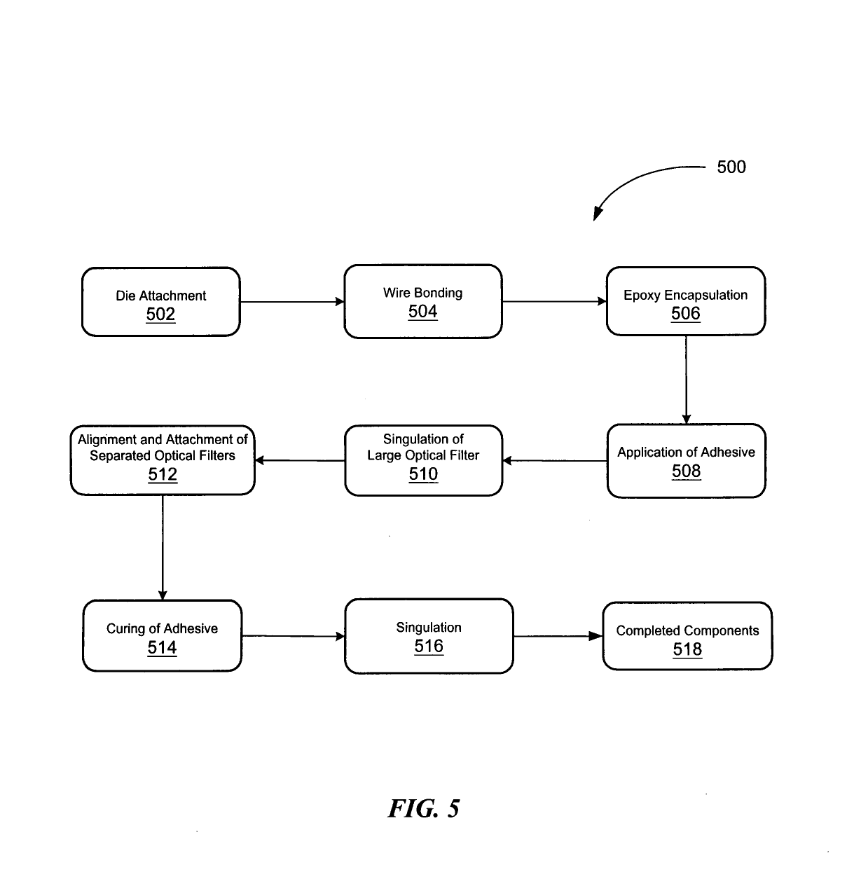

In FIG. 5, a flow chart of another example of an implementation of a process for the assembly of photonics components is shown. Steps 502, 504, and 506 are similar to steps 102, 104, and 106, respectively, of FIG. 1. The process starts in step 502, where an electronic component, e.g., a silicon wafer, containing multiple dies is attached to a circuit board, substrate, carrier, or lead-frame. The process then continues to the wire bonding process of step 504, which is the process of providing the electrical connection between the electronic component and the circuit board, substrate, carrier, or lead-frame using bonding wires. In step 506, the process continues to epoxy encapsulation, where the package of the circuit is encapsulated or packaged in a plastic material, which may be silicone or epoxy based. In step 508, an adhesive is applied to the encapsulated package produced in step 506. Again, the adhesive may be a glue, an epoxy resin, a light-curable adhesive, which may include an ultraviolet (“UV”) curable composition, and other attachment means.

In step 510, a single large optical device is singulated into a plurality of separate smaller optical devices. As an example, the optical device may be an optical filter fabricated on a large glass substrate and may include multiple substrates laminated together, and the smaller optical devices may be in either a circular, square, or rectangular configuration.

The process then proceeds to step 512, where the smaller optical devices produced in step 510 are individually aligned and attached to encapsulated package produced in step 506. In step 512, as an example, the smaller optical devices may be positioned equidistant along the X and Y axes of the encapsulated package 500 so as to allow optimal singulation; that is, the smaller optical devices may be positioned on the encapsulated package so as to maximize the number of components produced per each encapsulated package or to minimize the number of sawing cuts required to singulate the encapsulated package.

In step 514, the encapsulated package with the attached optical device is cured. Curing may involve the application of heat or illumination by short-wavelength light depending on the type of adhesive used. After curing, the encapsulated package is singulated in step 516. It is appreciated by those skilled in the art that there are various methods of singulation, e.g., laser scribing and diamond wheel sawing. As an example, sawing may be utilized to either partially cut or scribe the surface of the encapsulated package, with the encapsulated package then broken along the saw lines, or to completely cut through the encapsulated package.

The process ends in step 518 with multiple photonics components obtained from the singulation of the encapsulated package. Each of these photonics components may require additional processing to obtain the final product, e.g., testing, marking, etc. Marking may include placing corporate and product identification on a photonics component using ink or laser marking.

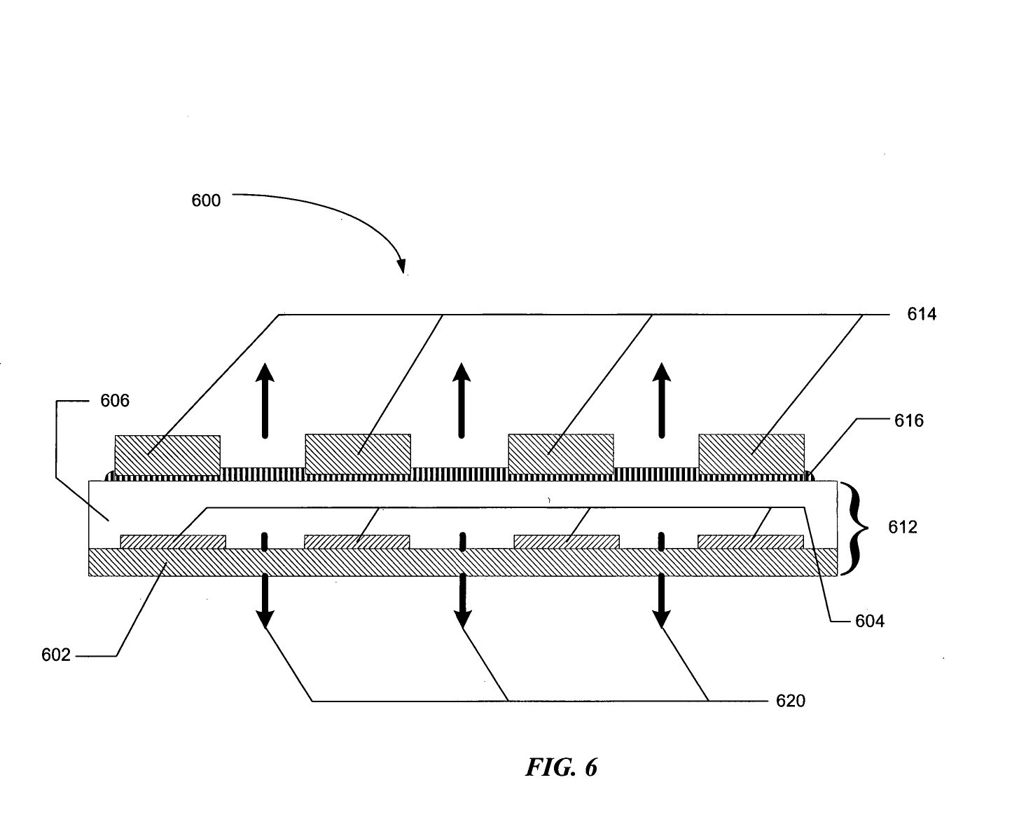

In FIG. 6, a cross-sectional view of another example embodiment of a single non-singulated package 600 having a plurality of photonics components produced by the process shown in FIG. 5 is shown before it is singulated in step 516 of FIG. 5. Single non-singulated package 600 is similar to the single non-singulated package 400, FIG. 4, with the exception that the optical devices that are placed onto encapsulation package 612 may include a plurality of the smaller separated optical devices 614, in contrast to FIG. 4 that shows a single large optical device 414. In FIG. 6, electronic components 604 are attached to substrate 602 utilizing encapsulant 606. The electronic components 604 and substrate 602 together form an encapsulated package 612. A plurality of optical devices 614, which in this example may be optical filters, may be attached to encapsulated package 612 by an adhesive 616 or other attachment means.

In FIG. 6, the single non-singulated package 600 is shown immediately prior to its entry into step 516 as shown in FIG. 5. Sawing lines 620 indicate where the single non-singulated package 600 will be cut. As noted above, singulation may be performed utilizing numerous methods, including, for example, by completely cutting through single non-singulated package 400 using a diamond saw, or by partially sawing and then breaking single non-singulated package 600. In FIG. 6, the sawing along sawing lines 620 creates cuts along the X axis of single non-singulated package 600. It is appreciated that additional cuts along the Y axis may be made to complete the singulation process. In one example method, this may be accomplished by a 90° rotation of the single non-singulated package 400 and repetition of the sawing along the Y axis of single non-singulated package 400.

As shown in FIG. 6, multiple separated optical devices 614 are individually aligned-and attached to encapsulated package 612 before the curing of the adhesive and the singulation of steps 514 and 516, respectively, of FIG. 5. The separated optical devices 514 may be positioned equidistant along the X and Y axes of the single non-singulated package 600 so as to allow optimal singulation, which may include alignment that minimizes the number of sawing lines required to produce a specified number of completed components or that maximizes the number of components produced per each encapsulated package 612.

It will be understood that the foregoing description of numerous implementations has been presented for purposes of illustration and description. It is not exhaustive and does not limit the claimed inventions to the precise form disclosed. Modifications and variations are possible in light of the above description or may be acquired from practicing the invention. The claims and their equivalents define the scope of the invention.

What is claimed:

1. A method for attaching an optical device to a single component having a plurality of encapsulated electronic packages, the method comprising:
applying an adhesive to the single component;
aligning the optical device relative to the single component;
attaching the optical device to the single component using the adhesive;
curing the single component with the attached optical device; and
singulating the single component into a plurality of separate encapsulated packages, each with a portion of the optical device attached.

2. The method of claim 1, wherein the optical device attached to the single component is an optical filter.

3. The method of claim 2, wherein the optical filter attached to the single component is an interference filter with a plurality of substrates configured to produce a predetermined resolution patterning.

4. The method of claim 2, wherein singulating the single component further includes sawing the single component.

5. The method of claim 2, wherein singulating the single component further includes
partially sawing the single component and
breaking the partially-sawed single component into the plurality of separate encapsulated packages

6. The method of claim 2, wherein singulating the single component further includes dry process dicing the single component into the plurality of separate encapsulated packages.

7. The method of claim 1, wherein the adhesive applied to the single component is an epoxy resin.

8. The method of claim 1, wherein the adhesive applied to the single component is an ultraviolet (“UV”) curable composition.

9. The method of claim 8, wherein the curing includes applying an UV light to the single component with the attached optical device.

10. A method for attaching optical devices to a single component having a plurality of encapsulated electronic packages, the method comprising:
singulating an unsingulated optical device having multiple optical devices into a plurality of separated optical devices;
applying an adhesive to the single component;
aligning each of the plurality of separated optical devices relative to the single component;
attaching each of the plurality of separated optical devices to the single component using the adhesive;
curing the single component with the attached plurality of separated optical devices; and
singulating the single component with the attached plurality of separated optical devices into a plurality of separate encapsulated packages, with each separate encapsulated package having a separated optical device attached after the singulation.

11. The method of claim 10, wherein aligning further includes positioning the plurality of separated optical devices on the single component so as to optimize the singulation of the single component.

12. The method of claim 11, wherein the unsingulated optical device is an optical filter.

13. The method, of claim 12, wherein the optical filter is an interference filter with a plurality of substrates configured to produce a predetermined resolution patterning.

14. The method of claim 11, wherein singulating the single component further includes sawing the single component with the plurality of separated optical devices attached.

15. The method of claim 11, wherein singulating the single component further includes
partially sawing the single component and
breaking the partially-sawed single component with the plurality of separated optical devices attached.

16. The method of claim 11, wherein singulating the single component further includes dry process dicing the single component with the plurality of separated optical devices attached.

17. The method of claim 11, wherein the adhesive applied to the single component is an epoxy resin.

18. The method of claim 11, wherein the adhesive applied to the single component is an UV curable composition.

19. The method of claim 18, wherein the curing further includes applying an UV light to the single component with the attached optical device.

20. The method of claim 11, further including marking each separate encapsulated package.
